(19) United States
(12) Patent Application Publication
(10) Pub. No.: US 2024/0147688 A1
(43) Pub. Date: May 2, 2024

(54) 3D CELLS AND ARRAY STRUCTURES

(71) Applicant: Fu-Chang Hsu, San Jose, CA (US)

(72) Inventor: Fu-Chang Hsu, San Jose, CA (US)

(21) Appl. No.: 18/499,432

(22) Filed: Nov. 1, 2023

Related U.S. Application Data
(60) Provisional application No. 63/421,522, filed on Nov. 1, 2022.
(60) Provisional application No. 63/458,634, filed on Apr. 11, 2023.
(60) Provisional application No. 63/459,406, filed on Apr. 14, 2023.
(60) Provisional application No. 63/460,406, filed on Apr. 19, 2023.
(60) Provisional application No. 63/463,040, filed on Apr. 30, 2023.
(60) Provisional application No. 63/465,526, filed on May 10, 2023.
(60) Provisional application No. 63/466,155, filed on May 12, 2023.
(60) Provisional application No. 63/467,004, filed on May 16, 2023.
(60) Provisional application No. 63/542,526, filed on Oct. 5, 2023.

(51) Int. Cl. H10B 12/00

(52) U.S. Cl. CPC H10B 12/00

(57) ABSTRACT

Various 3D memory cells, array architectures, and processes are disclosed. In an embodiment, a memory cell structure is provided that includes a vertical bit line, a first semiconductor layer surrounding a first portion of the vertical bit line, and a first gate surrounding the first semiconductor layer. The memory cell structure also includes a second semiconductor layer surrounding a second portion of the vertical bit line, and a gate dielectric layer surrounding a third portion of the vertical bit line. The gate dielectric layer separates the first semiconductor layer and the first gate from the second semiconductor layer.

### CROSS-REFERENCE TO RELATED APPLICATIONS

This application claims the benefit of priority under 35 U.S.C. 119(e) based upon U.S. Provisional patent application having Application No. 63/421,522 filed on Nov. 1, 2022, and entitled “3D Cell and Array Structures,” and U.S. Provisional patent application having Application No. 63/458,634 filed on Apr. 11, 2023, and entitled “3D Cell and Array Structures,” and U.S. Provisional patent application having Application No. 63/459,406 filed on Apr. 14, 2023, and entitled “3D Cell and Array Structures and Processes,” and U.S. Provisional patent application having Application No. 63/460,406 filed on Apr. 19, 2023, and entitled “3D Memory Cell and Array Structures,” and U.S. Provisional patent application having Application No. 63/463,040 filed on Apr. 30, 2023, and entitled “3D Memory Cell and Array Structures,” and U.S. Provisional patent application having Application No. 63/465,526 filed on May 10, 2023, and entitled “3D Cell and Array Structures,” and U.S. Provisional patent application having Application No. 63/466,155 filed on May 12, 2023, and entitled “3D Cell and Array Structures,” and U.S. Provisional patent application having Application No. 63/467,004 filed on May 16, 2023, and entitled “3D Cell and Array Structures,” and U.S. Provisional patent application having Application No. 63/542,526 filed on Oct. 5, 2023, and entitled “3D Array Structures and Processes,” all of which are hereby incorporated herein by reference in their entireties.

### FIELD OF THE INVENTION

The exemplary embodiments of the present invention relate generally to the field of memory, and more specifically to 3D memory cells and array structures and associated processes.

### BACKGROUND OF THE INVENTION

With the increasing complexity and density of electronic circuits, memory size, complexity, and cost are important considerations. One approach to increase memory capacity is to use a three-dimensional (3D) array structure. However, efficient, and cost-effective 3D array structures have not been fully realized.

### SUMMARY

In various exemplary embodiments, memory cells, array structures and processes are disclosed. For example, three-dimensional (3D) NOR-type cell and array structures and processes are disclosed. The disclosed embodiments are applicable to many technologies. For example, in one embodiment, dynamic random-access memory (DRAM) can be formed. In other embodiments, the invention is applicable to form a ferroelectric random-access memory (FRAM), resistive random-access memory (RRAM), phase change memory (PCM), and magneto-resistive random-access memory (MRAM). In another embodiment, the invention may be applied to form the memory elements called ‘synapses’ in artificial neural networks. In addition, the invention may be applied to any other applications not listed but remain within the scope of the invention.

In an exemplary embodiment, a memory cell structure is provided that comprises a vertical bit line, a first semiconductor layer surrounding a first portion of the vertical bit line, and a first gate surrounding the first semiconductor layer. The memory cell structure also comprises a second semiconductor layer surrounding a second portion of the vertical bit line, and a gate dielectric layer surrounding a third portion of the vertical bit line. The gate dielectric layer separates the first semiconductor layer and the first gate from the second semiconductor layer.

In an exemplary embodiment, a memory cell structure is provided that comprises a vertical bit line, a first semiconductor layer surrounding a first portion of the vertical bit line, and a first gate surrounding the first semiconductor layer. The memory cell structure also comprises a gate dielectric layer surrounding the first semiconductor layer and the first gate, and a second semiconductor layer surrounding a second portion of the vertical bit line and located below the bottom portion of the gate dielectric layer.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1A-C show an embodiment of 3D DRAM cell formed of a one-transistor-one-capacitor (1T1C) structure according to the invention.

FIGS. 2A-B show an embodiment of a 3D DRAM cell structure according to the invention.

FIGS. 3A-B show embodiments of 3D DRAM cell structure according to the invention.

FIGS. 4A-C show embodiments of a 3D DRAM cell structure according to the invention.

FIGS. 5A-C show embodiments of a 3D DRAM cell structure according to the invention.

FIGS. 6A-B show embodiments of 3D DRAM cell structure according to the invention.

FIGS. 7A-C show embodiments of 3D DRAM cell structure according to the invention.

FIGS. 8A-B show embodiments of a 3D DRAM cell structure according to the invention.

FIGS. 9A-B show embodiments of a 3D DRAM cell structure according to the invention.

FIGS. 10A-B show embodiments of a 3D DRAM cell structure according to the invention.

FIG. 11 shows an embodiment of a 3D DRAM array structure based on the cell structure shown in FIG. 1A according to the invention.

FIG. 12A shows an embodiment of a 3D DRAM array according to the invention.

FIG. 12B shows another embodiment of 3D DRAM array according to the invention.

FIGS. 13A-C show embodiments of a 3D DRAM cell structure according to the invention.

FIG. 13D shows an embodiment of a cell structure that is similar to the embodiment shown in FIG. 13A but has a different shape for the gate dielectric layer.

FIGS. 14A-C show embodiments of a 3D DRAM cell structure according to the invention.

FIGS. 15A-C show embodiments of a 3D DRAM cell structure according to the invention.

FIGS. 16A-B show embodiments of 3D DRAM cell structure according to the invention.

FIGS. 17A-B show embodiments of a 3D DRAM cell structure according to the invention.

FIGS. 18A-C show embodiments of a 3D DRAM cell structure according to the invention.

FIGS. 19A-C shows embodiments of a 3D DRAM cell structure according to the invention.

FIGS. 20A-C show embodiments of a 3D DRAM cell structure according to the invention.

FIG. 21A shows an embodiment of a structure formed using the cell structure shown in FIG. 20A.

FIG. 21B shows an embodiment of a structure formed using the cell structure shown in FIG. 13A.

FIGS. 22A-E show embodiments of cell structures according to the invention.

FIG. 23A shows an embodiment of a 3D array structure formed using the cell structure shown in FIG. 13A as an example according to the invention.

FIG. 23B shows an embodiment of 3D array structure formed using the cell structure shown in FIG. 16A as an example according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

Three-dimensional (3D) cell and array structures are disclosed. Embodiments of the invention are applicable to many memory technologies. For example, in one embodiment, the invention can be applied to form 3D dynamic random-access memory (DRAM). In another embodiment, the invention can be applied to form any other technologies suitable to form 3D cells and array structures, such as ferroelectric random-access memory (FRAM). These applications are within the scope of the invention.

For illustration, embodiments of the invention forming DRAM cells are described as examples. However, the materials of the components of the cell structures can be varied according to the cell technologies used within the scope of the invention.

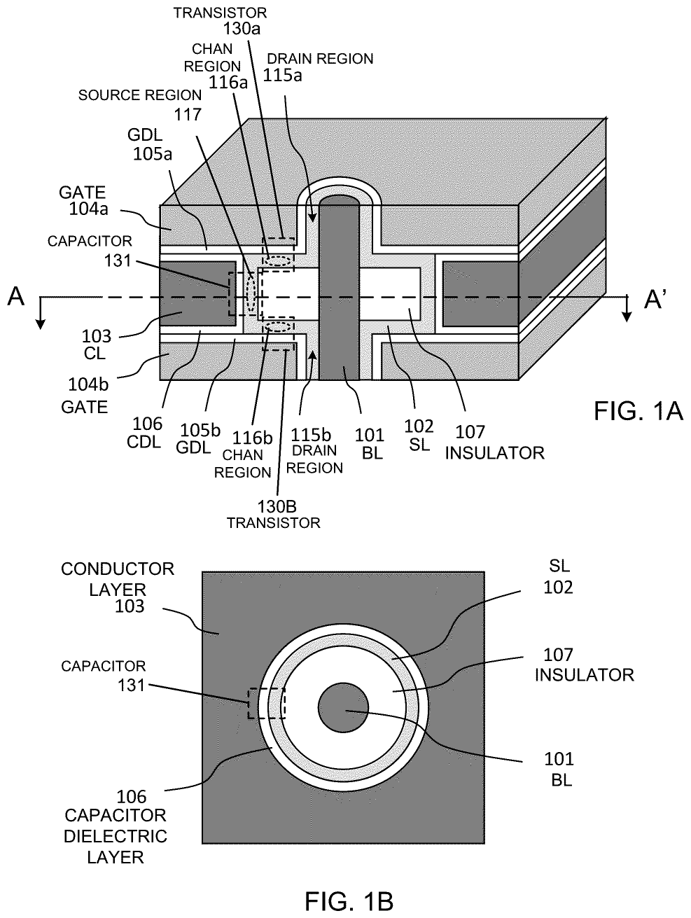

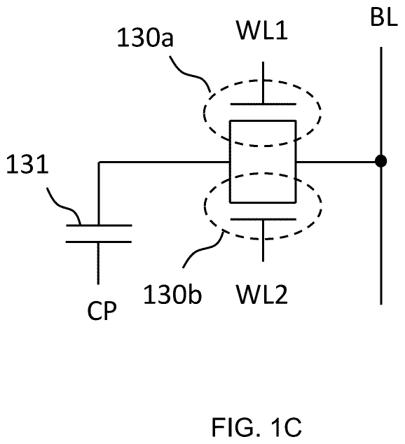

FIG. 1A show an embodiment of 3D DRAM cell formed of a one-transistor-one-capacitor (1T1C) structure according to the invention.

FIG. 1B shows a top view of a cross-section of the cell structure shown in FIG. 1A taken along line A-A′. It should be noted that for the purpose of clarity, the top view of the cross section shows the entire region around the bit line 101.

FIG. 1C shows an equivalent circuit of the cell structure shown in FIG. 1A. In one embodiment, the cell structure comprises a dual-gate select transistor that consists of two transistors 130a and 130b and a capacitor 131. The select transistors 130a and 130b are formed as thin-film transistors. The thin-film transistors provide better controllability for the channel over traditional P-N junction transistors. Therefore, the leakage current of the channel is greatly reduced compared to the P-N transistor. This allows the size of the capacitor 131 to be reduced.

The cell structure comprises a bit line (BL) 101 formed of conductor material such as metal or polysilicon material. The cell structure also comprises a semiconductor layer (SL) 102 comprising material, such as silicon, polysilicon, silicon-germanium, or oxide-based semiconductor such as indium gallium zinc oxide (IGZO). IGZO is known to have extremely low leakage current in the turn-off state, thus it may reduce the size requirement of the capacitor

It should be noted that the semiconductor material used in all the embodiments of cell structures constructed according to the invention comprises any suitable semiconductor material, such as silicon (Si), polysilicon (Poly-Si), germanium (Ge), silicon germanium (SiGe), gallium (Ga), Arsenic (As), Indium (In), gallium nitride (GaN), gallium-arsenide (GaAs), indium silicon (InSi), germanium indium (GeIn), indium gallium arsenide (InGaAs), silicon carbide (SiC), oxide based semiconductor such as Indium gallium zinc oxide (IGZO), and others suitable materials. For simplicity, the embodiments shown herein use silicon and polysilicon material as examples for illustration purposes. However, using any other semiconductor materials remains within the scope of the invention.

The semiconductor layer 102 forms the channel of the select transistors 130a and 130b. The semiconductor layer 102 can have heavy N-type or P-type doping to form N-channel or P-channel devices, respectively. The insulator material 107 comprises material, such as oxide or nitride material.

The gates 104a and 104b of the select transistors are formed of conductor material, such as metal or polysilicon material. Also provided are gate dielectric layers 105a and 105b comprising material such as thin oxide or high-K material such as HfO2. The gates 104a and 104b, gate dielectric layers (GDL) 105a and 105b, and the semiconductor layer 102 form the dual-gate thin-film transistors 130a and 130b as shown in FIG. 1C. Drain regions 115a and 115b of the transistors are connected to the bit line 101. Also shown are channel regions 116a and 116b. The source region 117 is part of a capacitor 131 that is formed by the source region 117, capacitor dielectric layer 106, and conductor layer 103 as further described below.

A capacitor dielectric layer (CDL) 106 comprises material, such as thin oxide or high-K material such as HfO2. A conductor layer (CL) 103 comprises material such as metal or polysilicon that forms an electrode of the capacitor 131. The conductor layer 103, capacitor dielectric layer 106, and the source region 117 of the semiconductor layer 102 form the capacitor 131 as shown in FIG. 1C.

In one embodiment, the gates 104a and 104b of the transistors are connected to word lines (WL). The conductor layer 103 is connected to a capacitor plate (CP) that is connected to a constant voltage, such as VDD or VSS (e.g., 0V).

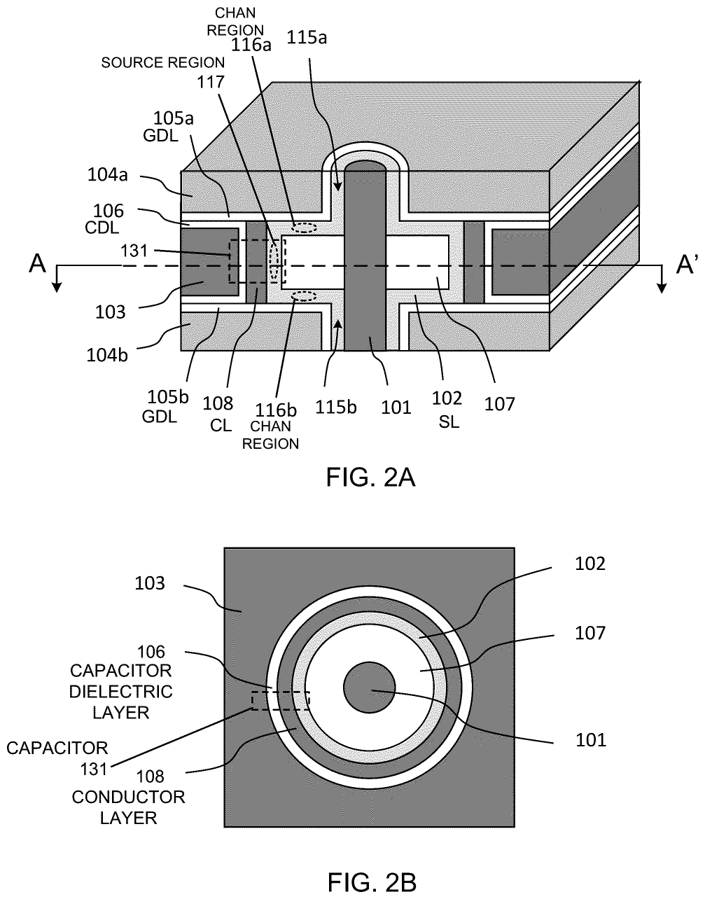

FIG. 2A shows an embodiment of a 3D DRAM cell structure according to the invention. This embodiment is similar to the embodiment shown in FIG. 1A except that a conductor layer (CL) 108 comprising material such as metal or polysilicon is formed between the capacitor dielectric layer 106 and the source region 117 of the semiconductor layer 102 to be a capacitor electrode to enhance the characteristics of the capacitor 131.

FIG. 2B shows a top view of a cross-section of the cell shown in FIG. 2A taken along line A-A′.

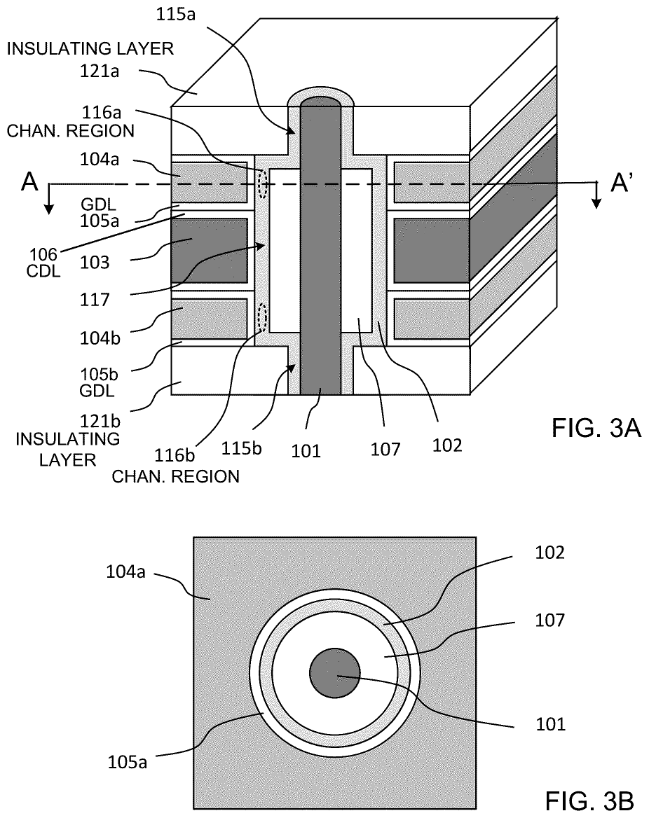

FIG. 3A shows an embodiment of a 3D DRAM cell structure according to the invention. This embodiment is similar to the embodiment shown in FIG. 1A except that the semiconductor layer 102 is formed in a different pattern or shape. For the embodiment shown in FIG. 1A, the channel regions 116a and 116b of the transistors are formed in a horizontal direction. For the embodiment shown in FIG. 3A, the channel regions 116a and 116b of the transistors are formed in a vertical direction. Also shown in FIG. 3A are insulating layers 121a and 121b comprising material such as oxide or nitride material.

FIG. 3B shows a top view of a cross-section of the cell structure shown in FIG. 3A taken along A-A′.

The structure of the vertical channels shown in this embodiment can be applied to all the other embodiments of the cell structures. For simplicity, the embodiment of the vertical channel structure for the other embodiments are not shown, however, these variations are within the scope of the invention.

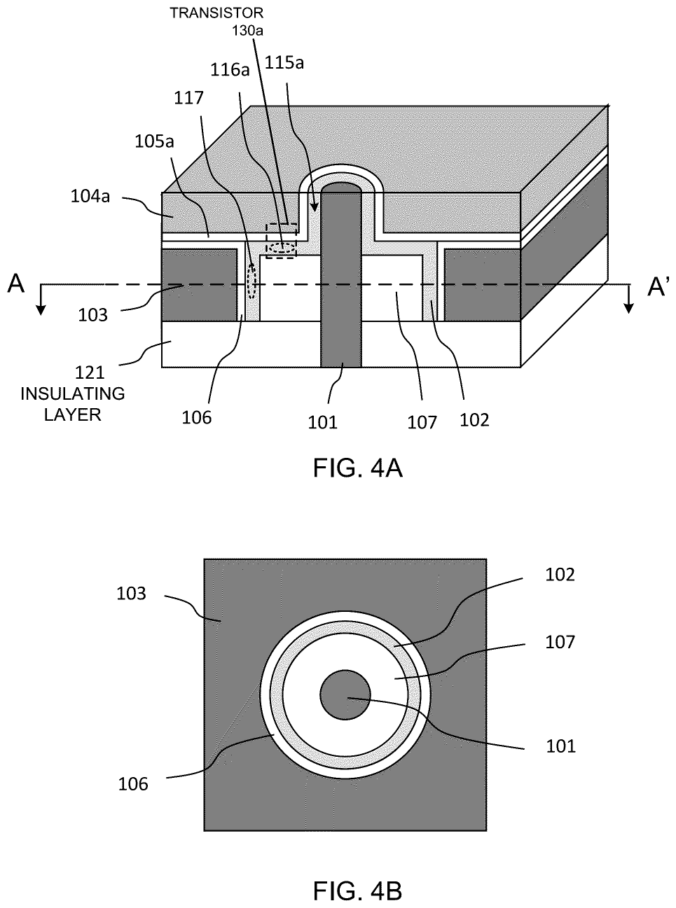

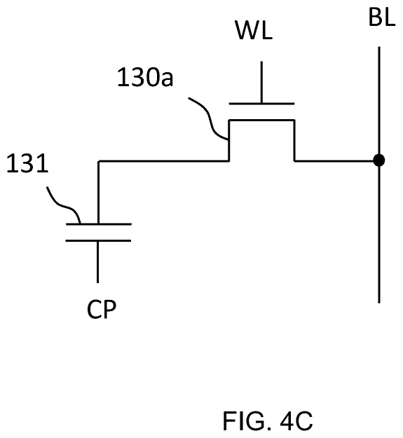

FIG. 4A shows an embodiment of a 3D DRAM cell structure according to the invention. This embodiment is similar to the embodiment shown in FIG. 1A except that the second gate 104b is eliminated. Also shown is an insulating layer 121 comprising material such as oxide or nitride material. This forms a single-gate select transistor 130a shown in FIG. 4C. The bottom portion of the semiconductor layer 102 and gate dielectric layer 106 are etched by using an isotropic etching process, such as wet etching through the space occupied by the insulating layer 121 before the insulating layer 121 is formed.

FIG. 4B shows a top view of a cross-section of the cell structure shown in FIG. 4A taken along line A-A′.

FIG. 4C shows an equivalent circuit of the cell structure shown in FIG. 4A.

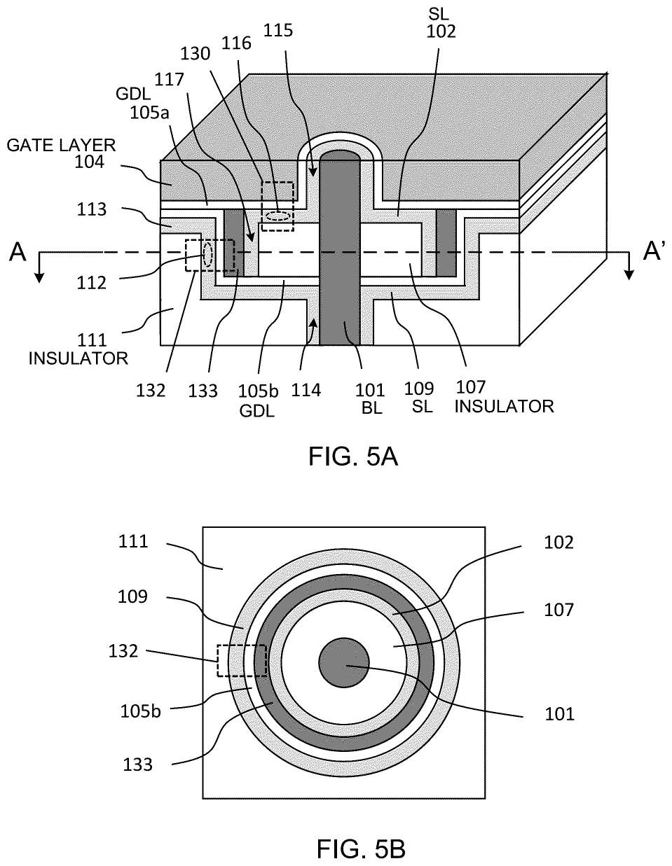

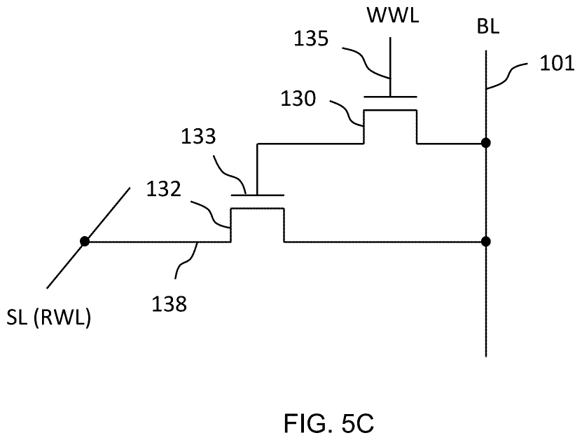

FIG. 5A shows an embodiment of a 3D DRAM cell structure according to the invention. This embodiment forms a two-transistor 2T DRAM gain cell, as the transistors 130 and 132 shown in FIG. 5A. The cell is called a gain cell because the read operation uses current sensing instead of charge-sharing that is typically used by traditional DRAM cells.

FIG. 5B shows a top view of a cross-section of the cell structure shown in FIG. 5A taken along line A-A′.

FIG. 5C shows an equivalent circuit of the cell structure shown in FIG. 5A. This circuit embodiment is similar to the circuit embodiment shown in FIG. 4C except that the capacitor 131 shown in FIG. 4C is replaced with a transistor 132 as shown in FIG. 5C.

The cell structure includes a write transistor 130 and a storage transistor 132. The gate 133 of the storage transistor 132 is used as a capacitor to store electric charge to represent data. During write operations, the selected write word line WWL 135 is supplied with a voltage to turn on the channel of the write transistor 130 to write data from the bit line 101 to the gate 133 of the storage transistor 132.

In one embodiment, the source of the storage transistor 132 is connected to a source line (SL) 138 (also called a read word line (RWL)). The drain of the storage transistor 132 is connected to the bit line 101. During read operations, the selected source line 138 is supplied with a selected voltage, such as VDD or VSS (0V). If the data stored in the gate 133 of the storage transistor 132 is 1 (VDD), the channel of the storage transistor 132 will be turned on to pass voltage from the source line 138 to the bit line 101. If the data stored in the gate 133 of the storage transistor 132 is 0 (VSS), the channel of the storage transistor 132 will be turned off, thus no current will flow from the source line 138 to the bit line 101. A sensing circuit (not shown) connected to the bit line 101 detect the current or voltage of the bit line 101 to determine the read data. Because the read operation is not performed by using a charge-sharing mechanism, the capacitor size of this cell is reduced. In addition, the read operation is non-destructive, thus the re-store operation after each read operation can be eliminated.

Referring again to FIG. 5A, the bit line 101 is formed of conductor material such as metal or polysilicon material. A semiconductor layer 102 comprises material such as silicon, polysilicon, silicon-germanium, or oxide-based semiconductor material such as indium gallium zinc oxide (IGZO). The material IGZO is known to have extremely low leakage current in the turned-off state, thus its use reduces the size requirement of the capacitor.

The semiconductor layer 102 forms the channel 116 of the write transistors 130 shown in FIG. 5C. The semiconductor layer 102 can have heavy N-type or P-type of doping to form N-channel or P-channel devices, respectively. An insulator 107 comprises material such as oxide or nitride.

The layer 104 forms the gate of the write transistor 130 shown in FIG. 5C. The gate 104 is formed of conductor material such as metal or polysilicon material. Gate dielectric layers 105a and 105b comprise material such as thin oxide material or high-K material such as HfO2. Also shown are the drain region 115, channel region 116, and source region 117 of the write transistor 130, respectively. The source region 117 is connected to a conductor 133 such as metal or polysilicon material that forms the gate 133 of the storage transistor 132 shown in FIG. 5C.

The semiconductor layer 109 forms the channel of the storage transistor 132 shown in FIG. 5C. The semiconductor layer 109 comprises material such as silicon, polysilicon, silicon-germanium material, or oxide-based semiconductor material such as indium gallium zinc oxide (IGZO). IGZO is known to have extremely low leakage current in turn-off state, thus it may reduce the size requirement of the capacitor. The semiconductor layer 109 has heavy N-type or P-type of doping to form N-channel or P-channel devices, respectively.

FIG. 5A shows a channel region 112, source region 113, and drain region 114 of the storage transistor 132, respectively. The channel region 112 is coupled to the gate 133. The drain region 114 is connected to the bit line 101. The source region 113 is connected to a source line 138 as shown in FIG. 5C. The insulator 111 comprises material such as oxide or nitride material.

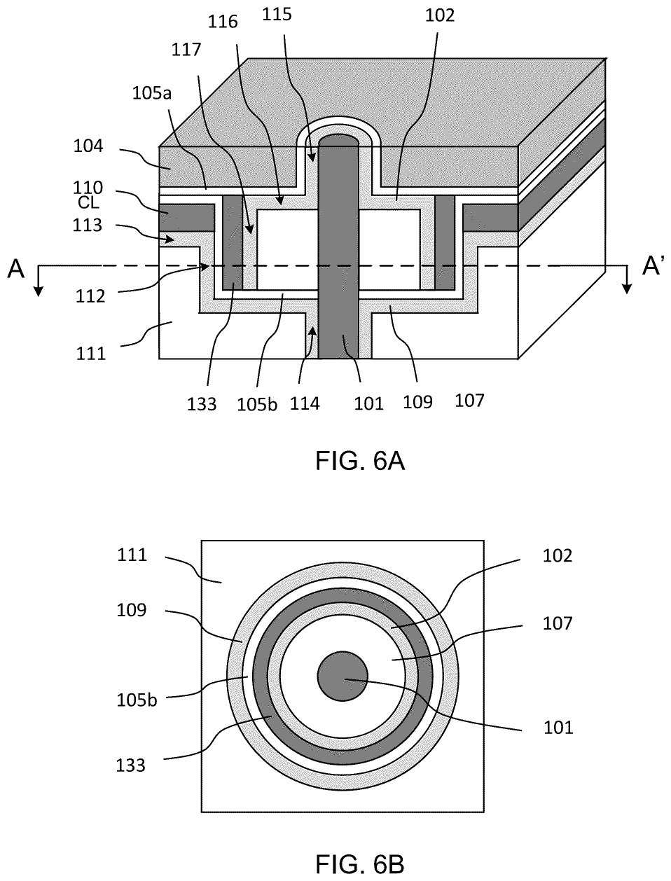

FIG. 6A shows an embodiment of a 3D DRAM cell structure according to the invention. This embodiment is similar to the embodiment shown in FIG. 5A except that a conductor layer 110 comprising material such as metal or polysilicon material is formed to contact with the source region 113 of the storage transistor 132 to reduce the resistance of the source line.

FIG. 6B shows a top view of a cross-section of the cell structure shown in FIG. 6A taken along line A-A′.

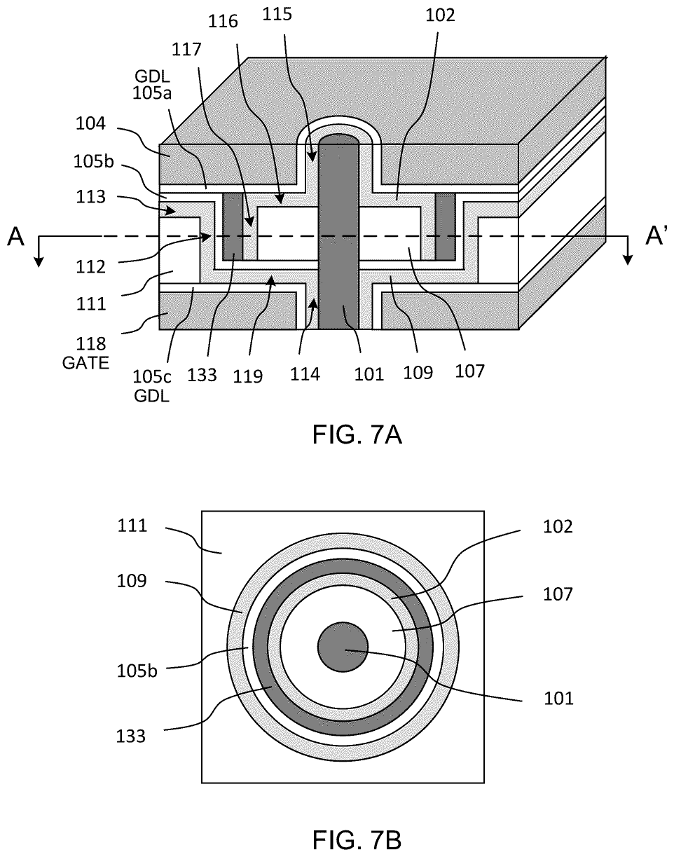

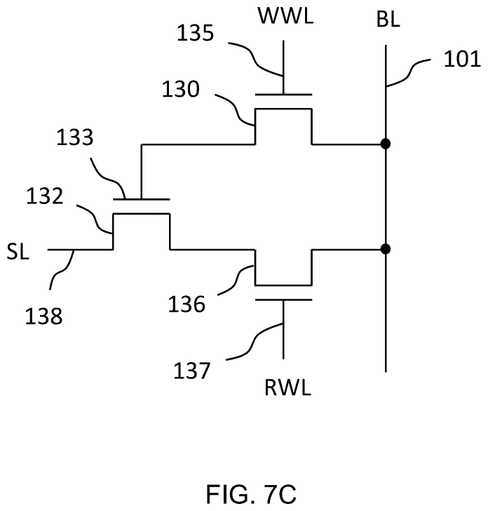

FIG. 7A shows an embodiment of a 3D DRAM cell structure according to the invention.

FIG. 7B shows a top view of a cross-section of the cell structure shown in FIG. 7A taken along line A-A′.

FIG. 7C shows an equivalent circuit of the cell structure shown in FIGS. 7A-B. This embodiment is similar to the embodiment shown in FIG. 5C except that a read transistor 136 is added between the storage transistor 132 and the bit line 101. This structure forms a three transistors (3T) gain cell. The gate of the read transistor 136 is connected to a read word line (RWL) 137. The source of the storage transistor 132 is connected to a source line (SL) 138. In one embodiment, the source line 138 is connected to a common voltage source, such as VDD or VSS.

During read operations, the selected read word line 137 is supplied with a voltage to turn on the channel of the read transistor 136. If the data stored in the gate 133 of the storage transistor 132 is 1 (VDD), the channel of the storage transistor 132 is turned on to pass the voltage from the source line 138 through the read transistor 136 to the bit line 101. If the data stored in the gate 133 of the storage transistor 132 is 0 VSS, the channel of the storage transistor 132 is turned off, thus no current will flow from the source line 138 to the bit line 101. A sensing circuit (not shown) connected to the bit line 101 detects the current or voltage of the bit line 101 to determine the read data.

Referring to FIG. 7A, this embodiment is similar to the embodiment shown in FIG. 5A except that a gate 118 and a gate dielectric layer 105c are formed as shown. The gate 118 is formed of conductor material, such as metal or polysilicon material. The gate dielectric layer 105c is formed of insulator material such as thin oxide or high-K material such as HfO2. The gate 118 is coupled to the channel region 119 of the semiconductor layer 109 to form the read transistor 136. The drain region 114 of the read transistor 136 is connected to the bit line 101. The source region of the read transistor is connected to the channel 112 of the storage transistor 132. The source region 113 of the storage transistor 132 is connected to a source line SL. Therefore, the cell circuit shown in FIG. 7C is formed. The reader is referred to the description of FIG. 5A for additional detailed description of the cell structure.

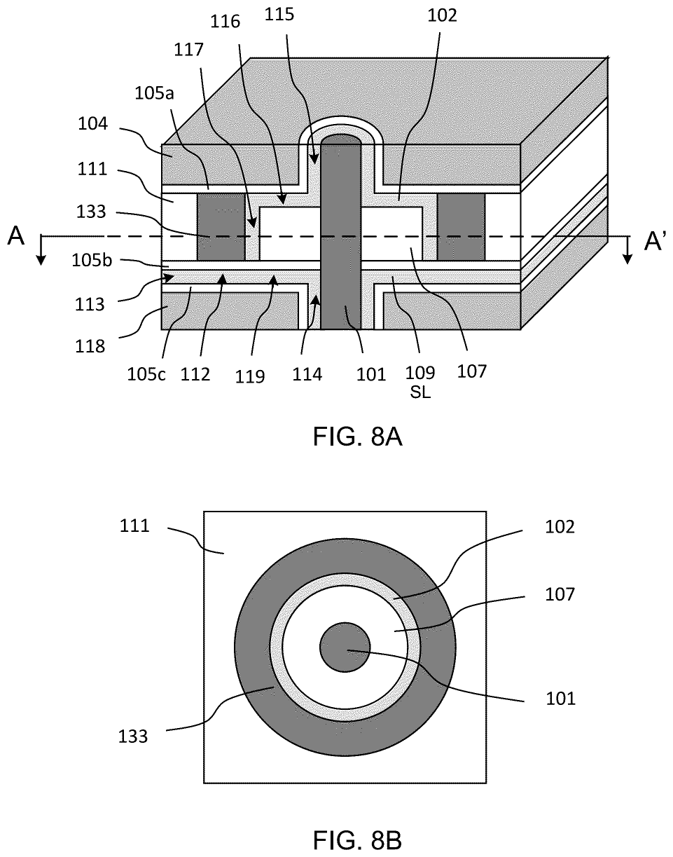

FIG. 8A shows an embodiment of a 3D DRAM cell structure according to the invention. FIG. 8B shows a top view of a cross-section of the cell structure shown in FIG. 8A taken along line A-A′. This embodiment is similar to the embodiment shown in FIG. 7A except that the semiconductor layer 109 is formed using a different pattern or shape. In FIG. 7A, the channel region 112 of the storage transistor 132 is formed in a vertical direction. In FIG. 8A, the channel region 112 of the storage transistor 132 is formed in a horizontal direction. The reader is referred to the description of FIG. 7A for a detailed description of the cell structure.

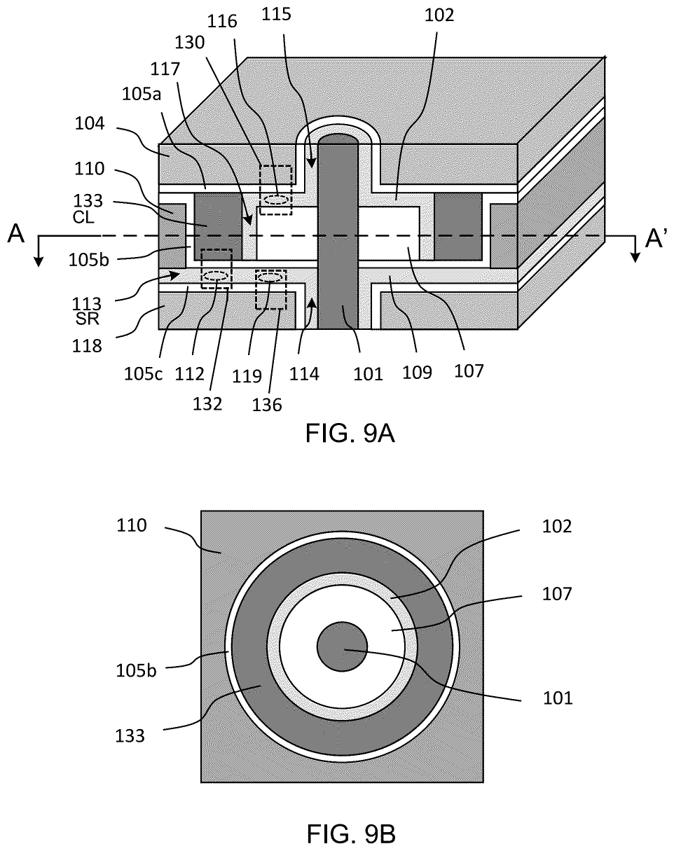

FIG. 9A shows an embodiment of a 3D DRAM cell structure according to the invention. FIG. 9B shows a top view of a cross-section of the cell structure shown in FIG. 9A taken along the line A-A′. This embodiment is similar to the embodiment shown in FIG. 8A except that a conductor layer 110 such as metal or polysilicon is formed and contacted with the source region (SR) 113 of the storage transistor 132 to reduce the resistance of the source line. The write transistor 130, storage transistor 132, and read transistor 136 are also shown. The reader is referred to the description of FIG. 8A for a detailed description of the cell structure.

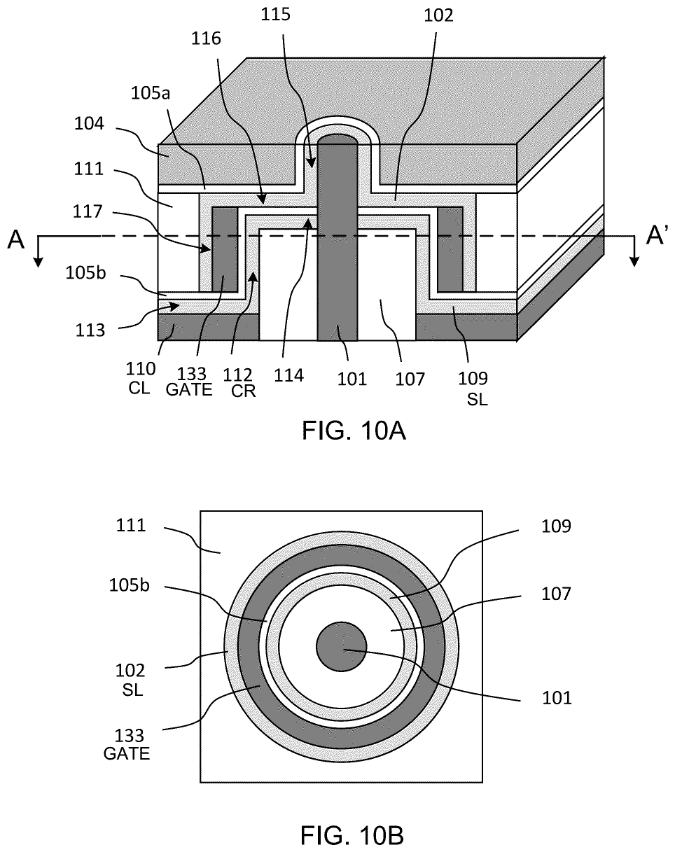

FIG. 10A shows an embodiment of a 3D DRAM cell structure according to the invention. FIG. 10B shows a top view of a cross-section of the cell structure shown in FIG. 10A taken along the lined A-A′. This embodiment is similar to the embodiment shown in FIG. 6A except that the semiconductor layer 109 and the conductor layer 110 are formed using different patterns or shapes. In FIG. 6A, the channel region 112 of the storage transistor 132 is formed outside of the gate 133. In FIG. 10A, the channel region 112 of the storage transistor 132 is formed inside of the gate 133. The reader is referred to the description of FIG. 6A for a detailed description of the cell structure.

Although the embodiments of the 3D cell structures shown in FIG. 1A to FIG. 10B use DRAM cells as an example, the cell structures disclosed are applicable to any other 3D cell technologies, such as ferroelectric random-access memory (FRAM). The materials of the components used in the disclosed cell structures can be varied according to the various technologies. These variations and modifications are within the scope of the invention.

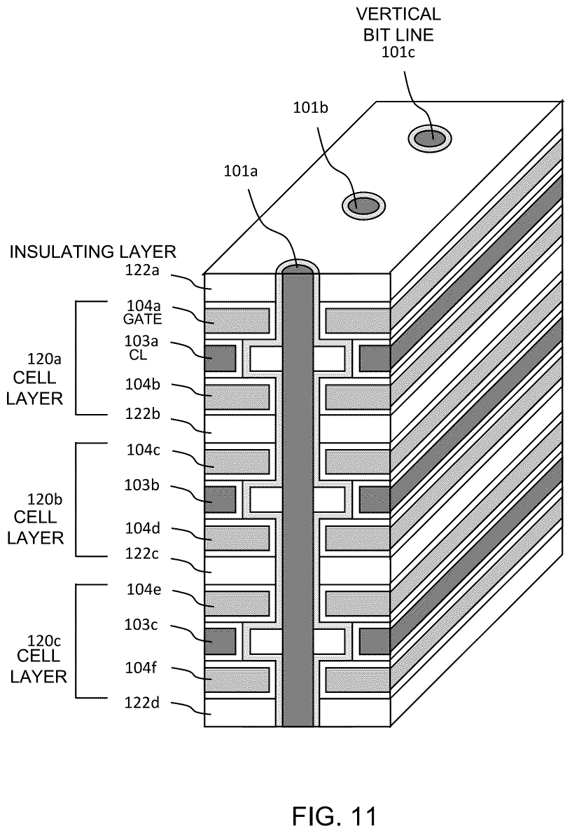

FIG. 11 shows an embodiment of a 3D DRAM array structure based on the cell structure shown in FIG. 1A according to the invention. Although the cell structure shown in FIG. 1A is used as an example, embodiments of the array structure can be formed using any of the cell structures shown in FIG. 1A to FIG. 10B. For simplicity, the embodiments using other cell structures will not be shown. However, these embodiments are within the scope of the invention.

As shown in FIG. 11, the 3D array structure comprises multiple layers of cells to form a stack. Three cell layers comprising cell layers 120a to 120c are shown as an example. The array also includes insulating layers 122a to 122d comprising material, such as oxide material, to separate the cell layers. Also provided are vertical bit lines 101a to 101c and gates 104a to 104f of the select transistors of the cells. The gates 104a to 104f are connected to word line WL signals. The array also includes conductor layers 103a to 103c that form capacitor plates. The conductor layers 103a to 103c are connected to a common voltage source, such as VDD or VSS.

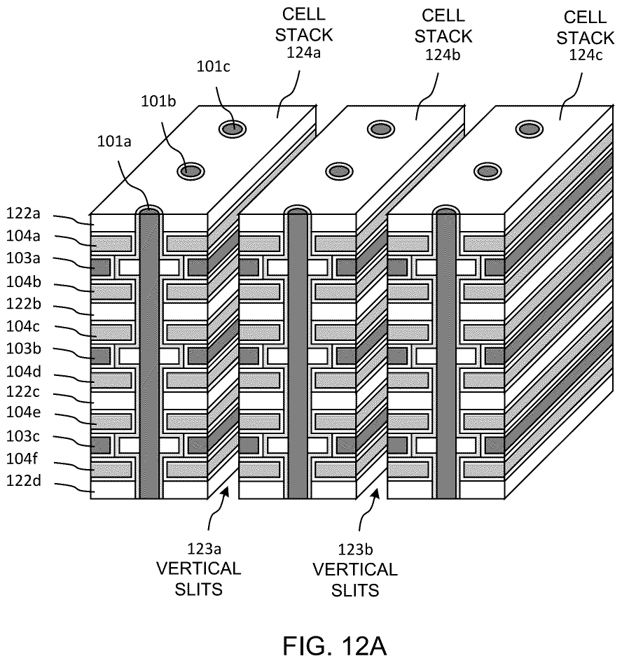

FIG. 12A shows an embodiment of a 3D DRAM array according to the invention. This array comprises multiple cell stacks 124a to 124c such as the cell stack as shown in FIG. 11. The cell stacks 124a to 124c are separated by vertical slits, such as slits 123a and 123b. In one embodiment, the vertical slits 123a and 123b are filled with insulator material (not shown in FIG. 12A) such as oxide or nitride material.

FIG. 12B shows another embodiment of a 3D DRAM array according to the invention. This embodiment is similar to the embodiment shown in FIG. 12A except that the vertical slits 123a and 123b shown in FIG. 12A are filled with conductor material, such as metal or polysilicon material, to form vertical capacitor plates 125a and 125b. The vertical capacitor plates 125a and 125b are connected to the conductor layers, such as layers 103a to 103c. Insulating layers, such as layers 126 are formed on the sidewall of the word lines, such as word lines 104a to 104f to prevent the word lines 104a to 104f from shorting to the vertical capacitor plates 125a and 125b.

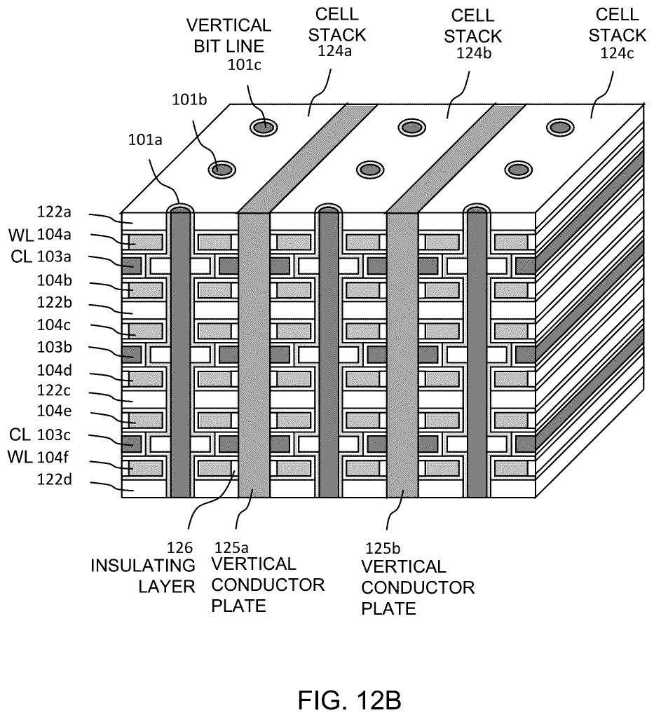

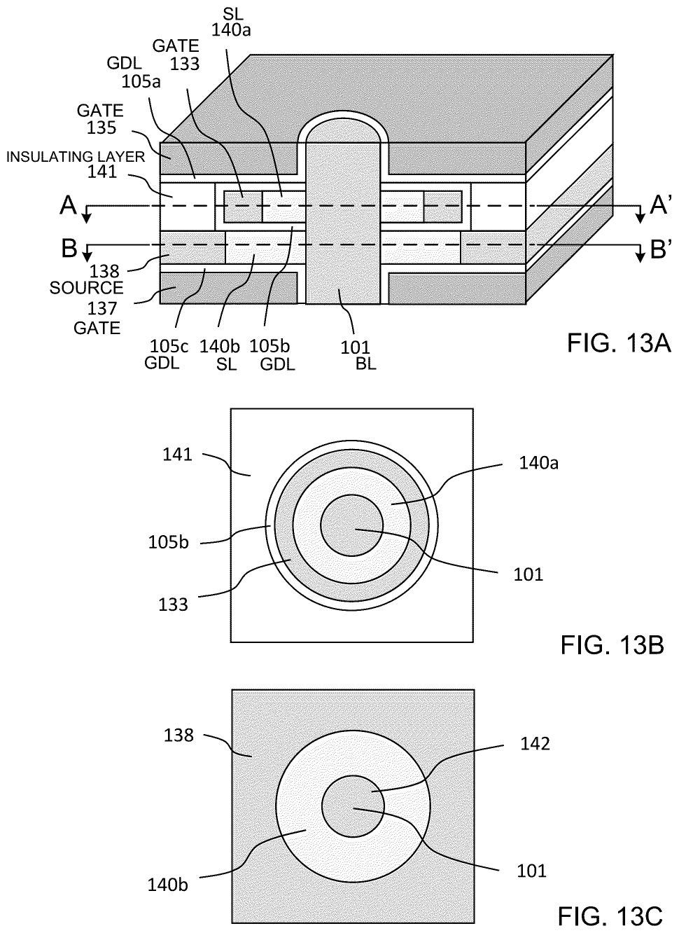

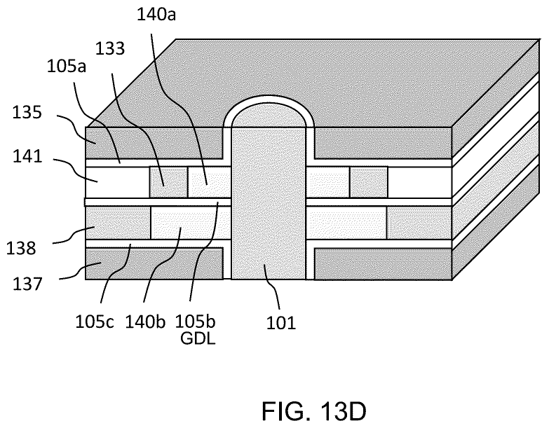

FIG. 13A shows an embodiment of a 3D DRAM cell structure according to the invention. FIGS. 13B-C show top views of cross-sections of the cell structure shown in FIG. 13A taken along line A-A′ and line B-B′, respectively. The equivalent circuit of this embodiment is shown in FIG. 7C. The gates 135 and 137 are part of the write transistor 130 and read transistor 136 as shown in FIG. 7C, respectively. The gates 135 and 137 are formed of conductor material, such metal or heavily doped polysilicon material. The gates 135 and 137 are connected to the write word line WWL and the read word line RWL, respectively.

FIG. 13A also shows the gate 133 of the storage transistor 132 as shown in FIG. 7C. The gate 133 is formed of conductor material, such as metal or heavily doped polysilicon material. The gate 133 is used as a storage node to store the data (VDD or VSS) to turn on or off the storage transistor 132. Also shown are gate dielectric layers 105a to 105c comprising material, such as oxide or high-K material such as hafnium oxide (HfO2). Semiconductor layers 140a and 140b form the channels of the transistors. The semiconductor layers 140a and 140b are formed of any suitable semiconductor material, such as silicon, polysilicon, silicon germanium (SiGe), Indium gallium zinc oxide (IGZO), and many others. In one embodiment, the semiconductor layers 140a and 140b are thin layers with N+ or P+ type of doping to form junction-less thin-film transistors.

FIG. 13A also shows a bit line 101 formed of conductor material, such as metal or semiconductor material such as heavily doped polysilicon. A source line (source) 138 is formed of conductor material such as metal or semiconductor material, such as heavily doped polysilicon. Also provided is an insulating layer 141 comprising material such as oxide or nitride material.

To write to the cell, the gate 135 is supplied with a voltage higher than the threshold voltage (Vt) to turn on the channel 140a. This allows electric charges, such as electrons, to flow from the bit line 101 to the gate 133. When the gate 135 is supplied with a voltage lower than the threshold voltage, the channel 140a is turned off and the electric charges are trapped inside the gate 133.

If the voltage stored in the gate 133 is higher than the threshold voltage, the gate 133 turns on the channel 140b under the gate 133. If the voltage stored in the gate 133 is lower than the threshold voltage, the storage node 133 turns off the channel 140b under the gate 133.

To read the data, the gate 137 is supplied with a voltage higher than the threshold voltage to turn on the channel 140b portion that is not covered by the gate 133. The bit line 101 and the source line 138 are supplied with different voltages, such as 1V and 0V, respectively. If the channel 140b under the gate 133 is on, current flows from the bit line 101 to the source line 138. If the channel 140b under the gate 133 is off, current does not flow from the bit line 101 to the source line 138. A sensing circuit, such as a sense amplifier can be coupled to the bit line 101 or source line 138 to detect the current to determine the data.

It should be noted that for all the embodiments of the cell structures shown herein, the shapes and dimensions of the components shown for the cell structures are exemplary. It is obvious that the components can have other various shapes and dimensions. These variations are within the scope of the invention.

In another embodiment, the shapes of the bit line 101, the channels 140a and 140b, and the gate 133 show in FIGS. 13A-C are formed in different shapes such as square, rectangular, triangular, or oval shapes.

FIG. 13D shows an embodiment of a cell structure that is similar to the embodiment shown in FIG. 13A but has a different shape for the gate dielectric layer 105b. Similar to FIG. 13A and FIG. 13D, all the gate dielectric layers in other embodiments, such as gate dielectric layers 105a to 105c shown in FIGS. 1A-B can be formed in different shapes. These variations are within the scope of the invention.

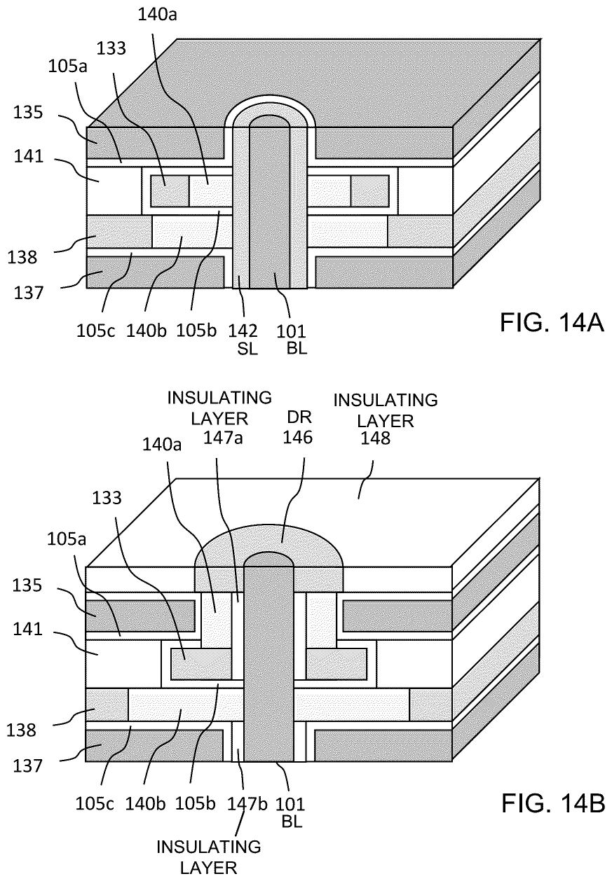

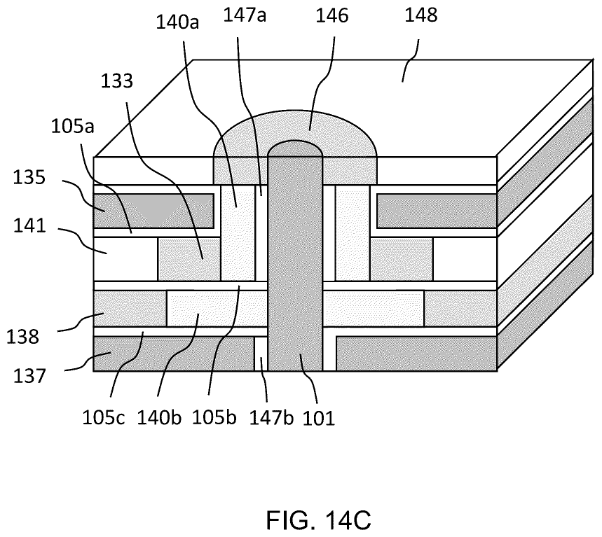

FIG. 14A shows an embodiment of a 3D DRAM cell structure according to the invention. This embodiment is similar to the embodiment shown in FIG. 13A except that the bit line 101 is formed of a conductor material, such as metal and a semiconductor layer 142 comprising material such as heavily doped silicon or polysilicon material, is formed to be a drain region or a buffer layer between the bit line 101 and the channels 140a and 140b.

FIG. 14B shows an embodiment of a 3D DRAM cell structure according to the invention. This embodiment is similar to the embodiment shown in FIG. 13A except that the channel 140a is formed in a vertical direction instead of in a horizontal direction. A drain region (DR) 146 is formed of conductor material, such as metal or semiconductor such as heavily doped silicon or polysilicon material. Also provided are insulating layers 147a, 147b, and 148 comprising material such as oxide or nitride material.

FIG. 14C shows an embodiment of a 3D DRAM cell structure according to the invention. This embodiment is similar to the embodiment shown in FIG. 14B except that the gate 133 is formed in a different location.

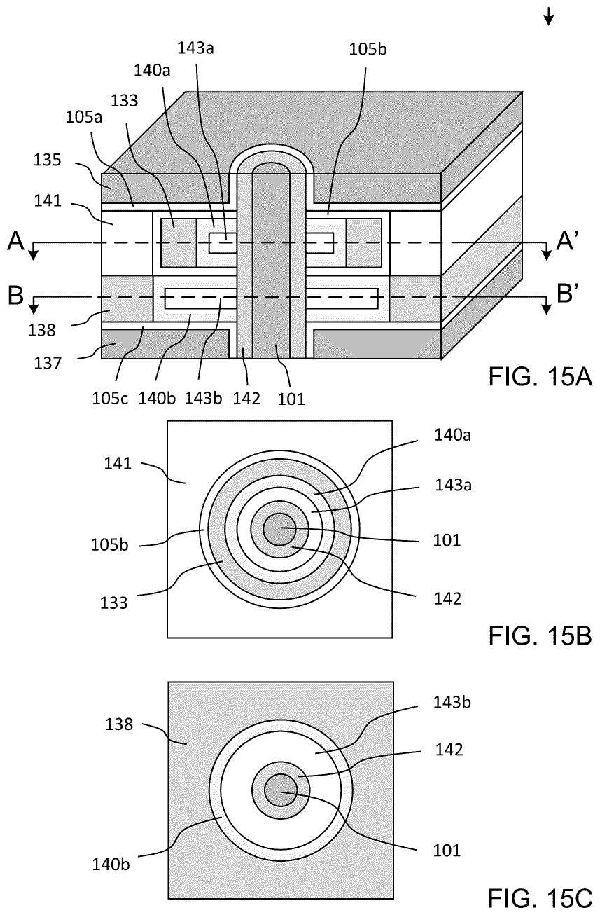

FIG. 15A shows an embodiment of a 3D DRAM cell structure according to the invention. FIGS. 15B-C show top views of cross-sections of the cell structure shown in FIG. 15A taken along the line A-A′ and the line B-B′, respectively. This embodiment is similar to the embodiment shown in FIG. 14A except that the channels 140a and 140b are formed in different shapes. In this embodiment, the channels 140a and 140b are formed as semiconductor layers enclosing insulating layers 143a and 143b, respectively.

In one embodiment, the structure shown in FIG. 15A is formed by using the following steps. First, using an isotropic etching process, such as wet etching to form recesses in the layers 133 and 138. Second, a thin-film deposition process, such as atom layer deposition (ALD) or epitaxial growth process, is used to form a semiconductor layer 140a and 140b on the surface of the sidewalls of the recesses. Next, depositing an insulator 143a and 143b to fill the recesses. The channels 140a and 140b are formed separately.

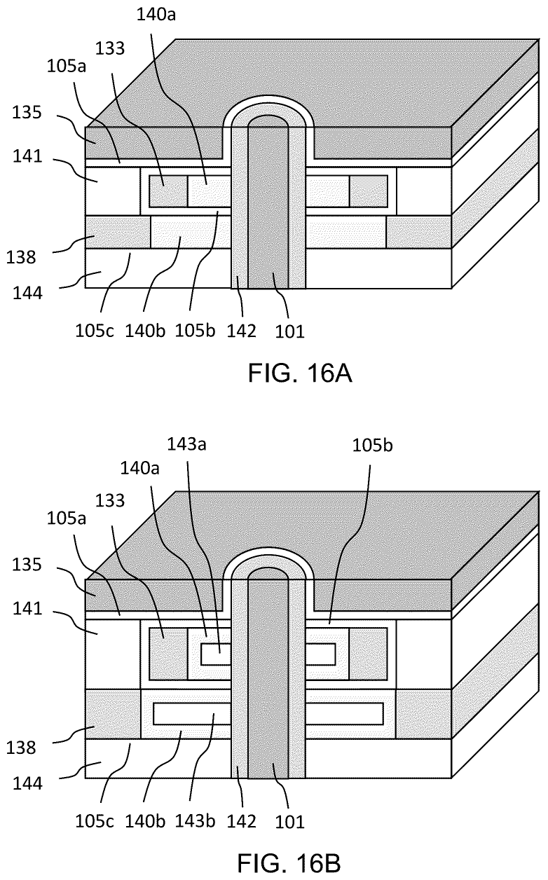

FIG. 16A shows an embodiment of a 3D DRAM cell structure according to the invention. This embodiment is similar to the embodiment shown in FIG. 14A except that the gate 137 and the gate dielectric layer 105c are eliminated. This forms a cell structure for the equivalent circuit shown in FIG. 5C.

FIG. 16B shows an embodiment of a 3D DRAM cell structure according to the invention. This embodiment is similar to the embodiment shown in FIG. 15A except that the gate 137 and the gate dielectric layer 105c are eliminated. This forms a cell structure for the equivalent circuit shown in FIG. 5C.

Similar to the embodiments shown in FIGS. 16A-B, the gate 137 and the gate dielectric layer 105c in all the other embodiments of cell structures shown in FIGS. 13A-21B can be eliminated to form cell structures for the equivalent circuit shown in FIG. 5C.

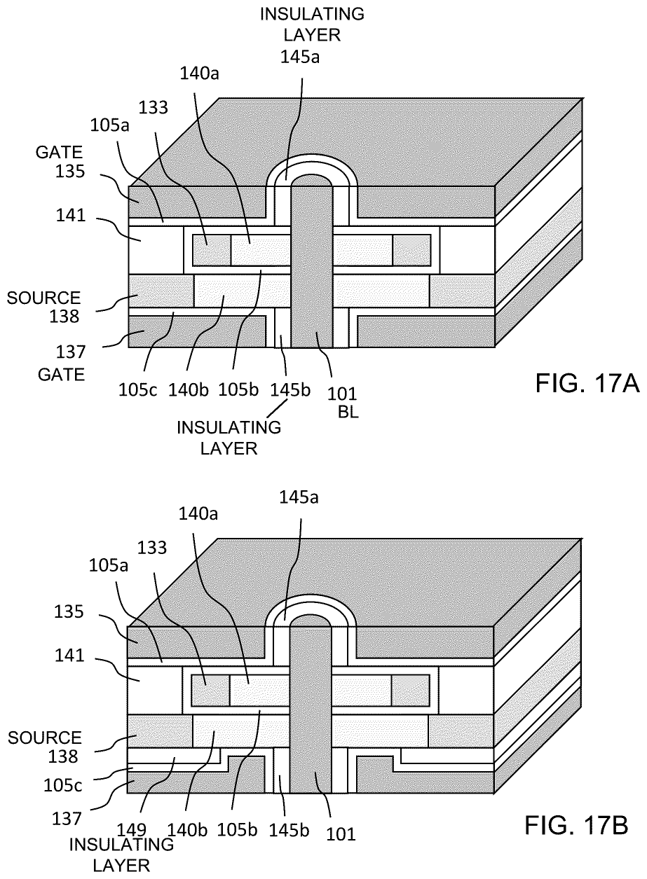

FIG. 17A shows an embodiment of a 3D DRAM cell structure according to the invention. This embodiment is similar to the embodiment shown in FIG. 13A except that additional insulating layers 145a and 145b comprising material such as oxide or nitride material are formed between the bit line 101 and the gates 135 and 137. This reduces the parasitic capacitances and noise coupling between the bit line 101 and the gates 135 and 137. Similar to the embodiment shown in FIG. 17A, the additional insulating layers 145a and 145b can be added to all the other embodiments of cell structures shown in FIGS. 13A-21B.

FIG. 17B shows an embodiment of a 3D DRAM cell structure according to the invention. This embodiment is similar to the embodiment shown in FIG. 17A except that additional insulating layers 149 comprising material such as oxide or nitride material is formed between the gate 137 and the source line 138. This reduces the parasitic capacitances and noise coupling between the gate 137 and the source line 138. Similar to the embodiment shown in FIG. 17B, the additional insulating layer 149 can be added to all the other embodiments of cell structures shown in FIGS. 13A-21B.

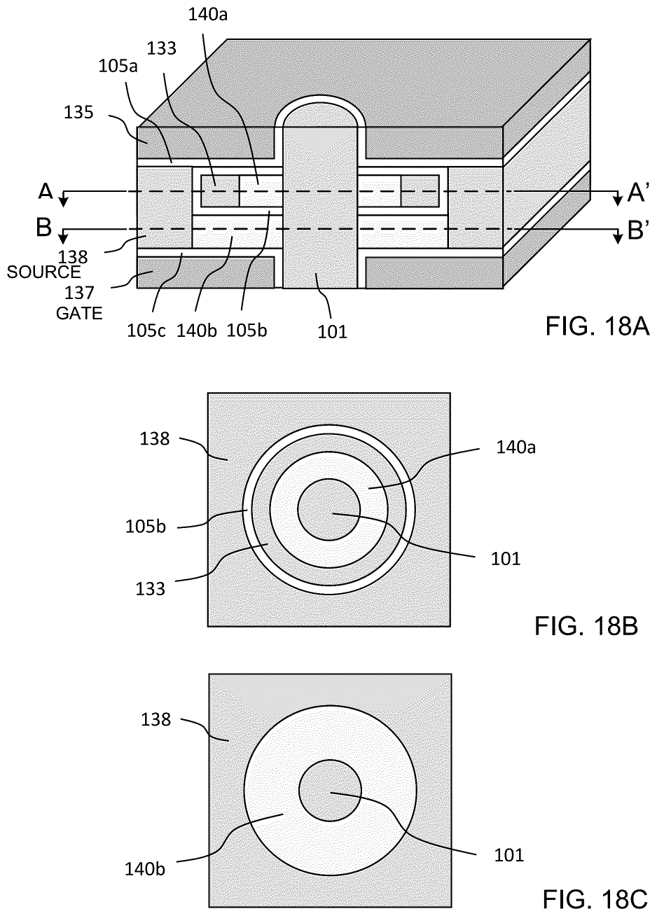

FIG. 18A shows an embodiment of a 3D DRAM cell structure according to the invention. FIGS. 18B-C show top views of cross-section of the cell structure shown in FIG. 18A taken along line A-A′ and line B-B′, respectively. This embodiment is similar to the embodiment shown in FIG. 13A except that the source line 138 is formed in a different shape.

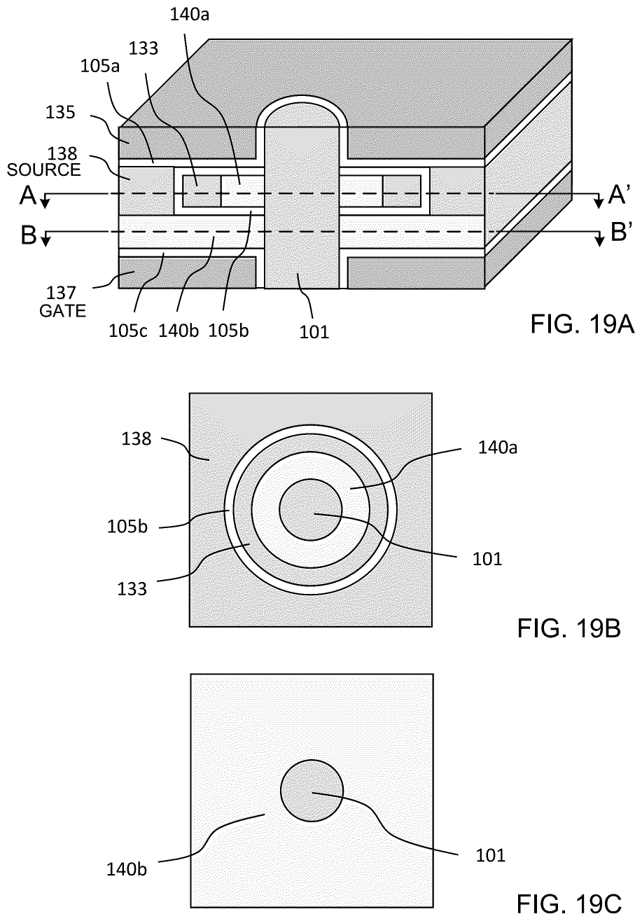

FIG. 19A shows an embodiment of a 3D DRAM cell structure according to the invention. FIGS. 19B-C show top views of cross-sections of the cell structure shown in FIG. 19A taken along line A-A′ and line B-B′, respectively. This embodiment is similar to the embodiment shown in FIG. 13A except that the source line 138 is formed in a different shape.

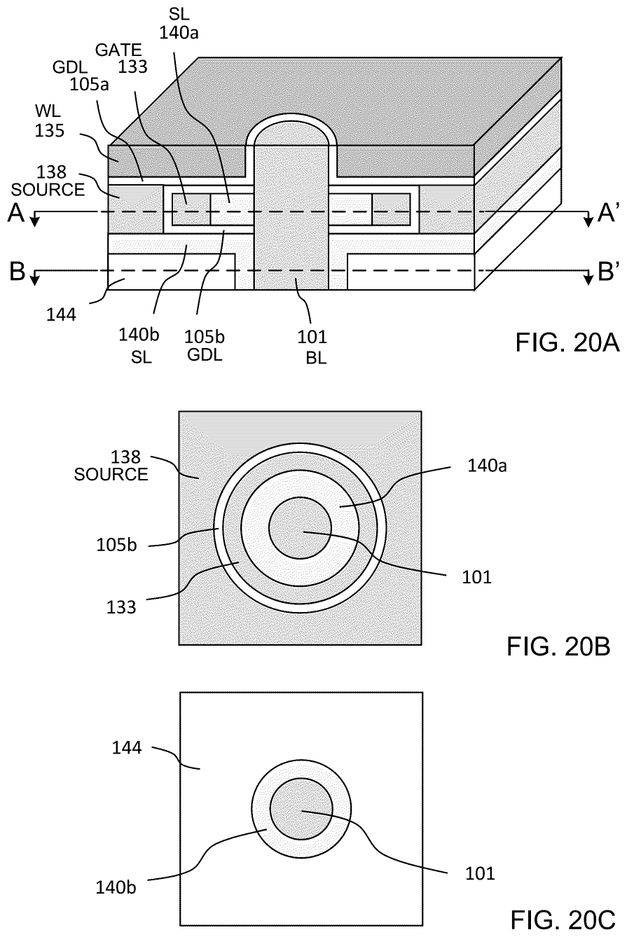

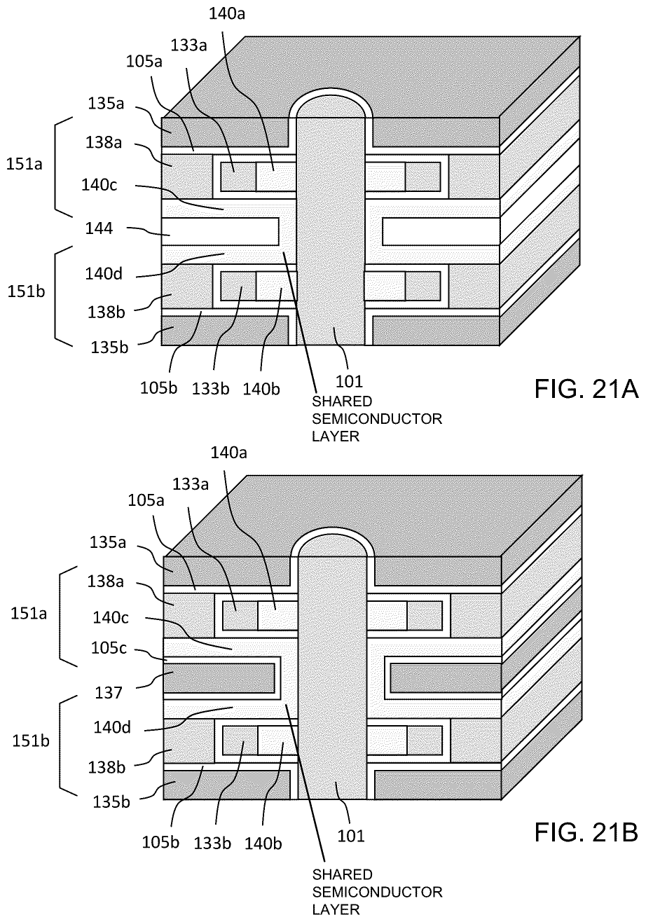

FIG. 20A shows an embodiment of a 3D DRAM cell structure according to the invention. FIGS. 20B-C show top views of cross-sections of the cell structure shown in FIG. 20A taken along line A-A′ and line B-B′, respectively. This embodiment is similar to the embodiment shown in FIG. 16A except that the source line 138 is formed in a different shape. In this embodiment, the semiconductor layer of the channel 140b is formed in the shape as shown. This shape allows the semiconductor layer for the channel 140b to be shared with the adjacent cell located under the cell, as illustrated in FIG. 21A. Also shown in FIG. 20A is an insulating layer 144 comprising material such as oxide or nitride material.

FIG. 21A shows an embodiment of a structure formed using the cell structure shown in FIG. 20A. Two cells 151a and 151b are shown as an example. The cells 151a and 151b share the semiconductor layer for the channels 140c and 140d.

FIG. 21B shows an embodiment of a structure formed using the cell structure shown in FIG. 13A. Two cells 151a and 151b are shown as an example. Similar to the embodiment shown in FIG. 21A, the cells 151a and 151b share the semiconductor layer for the channels 140c and 140d as shown.

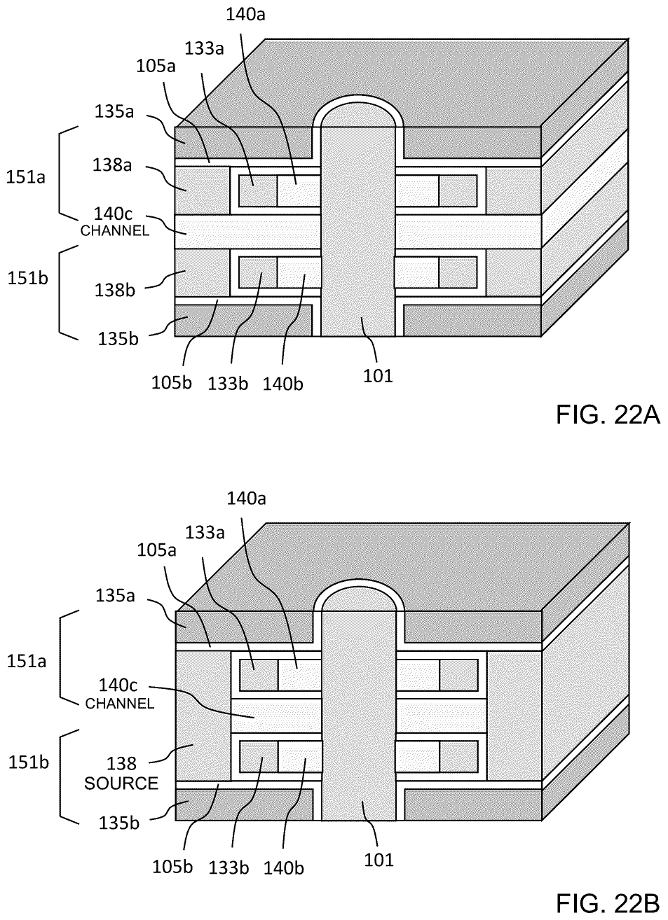

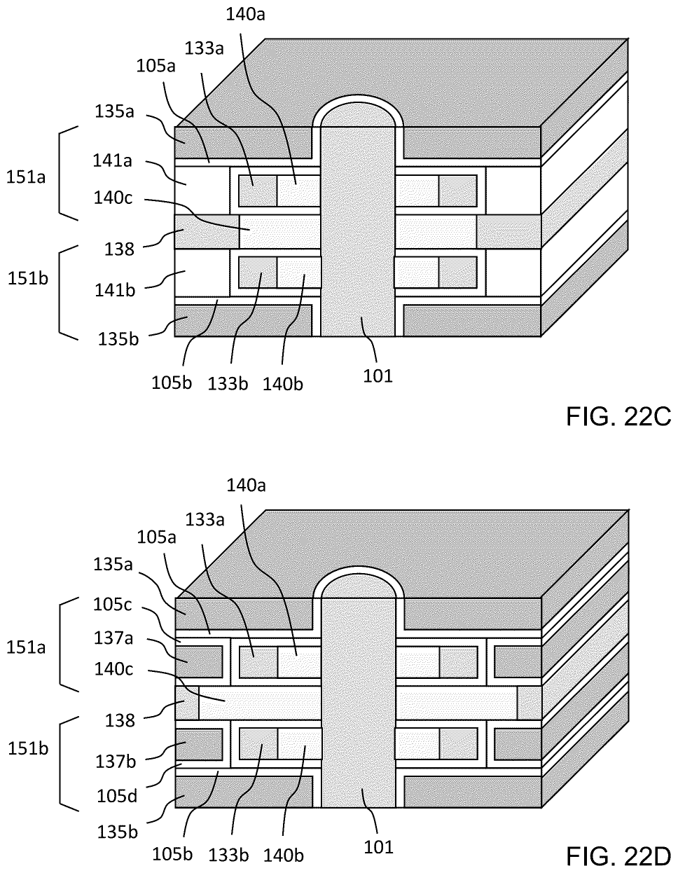

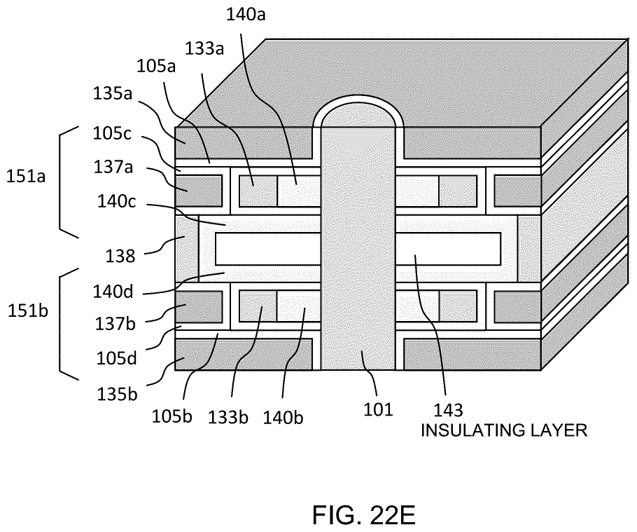

FIG. 22A shows an embodiment of a cell structure according to the invention. This embodiment is similar to the embodiment shown in FIG. 21A except that the channel 140c is formed in a different shape. In this embodiment, the channel 140c is formed as a layer. Because the channel 140c is shared by two cells 151a and 151b, the two cells 151a and 151b can be used to store one data value.

FIG. 22B shows an embodiment of a cell structure according to the invention. This embodiment is similar to the embodiment shown in FIG. 22A except that the source line 138 is formed in a different shape. In this embodiment, the channel 140c is formed as a disc similar to the disc 140b shown in FIG. 18C.

FIG. 22C shows an embodiment of a cell structure according to the invention. This embodiment is similar to the embodiment shown in FIG. 22B except that insulating layers 141a and 141b comprising material such as oxide or nitride material are formed as shown.

FIG. 22D shows an embodiment of a cell structure according to the invention. This embodiment is similar to the embodiment shown in FIG. 22C except that the insulating layers 141a and 141b are replaced with the read word lines 137a and 137b. Gate dielectric layers 105c and 105d are provided that comprise material such as oxide or high-K material such as hafnium oxide HfO2. During read operations, selected read word lines 137a and 137b are supplied with a voltage to turn on the channel 140c under the read word lines. The unselected read word lines 137a and 137b are supplied with a voltage to turn off the channel 140c under the read word lines. This allows current to flow only from the selected cell to the source line 138.

FIG. 22E shows another embodiment of the cell structure according to the invention. This embodiment is similar to the embodiment shown in FIG. 22D except the channel 140c is formed in a different shape or pattern. An insulating layer 143 comprises material such as oxide or nitride material that isolates the channels 140c and 140d. This allows the cells 151a and 151b to be independently read by selecting the read word line 135a or 135b to turn on the channel 140c or 140d under the selected read word line, respectively.

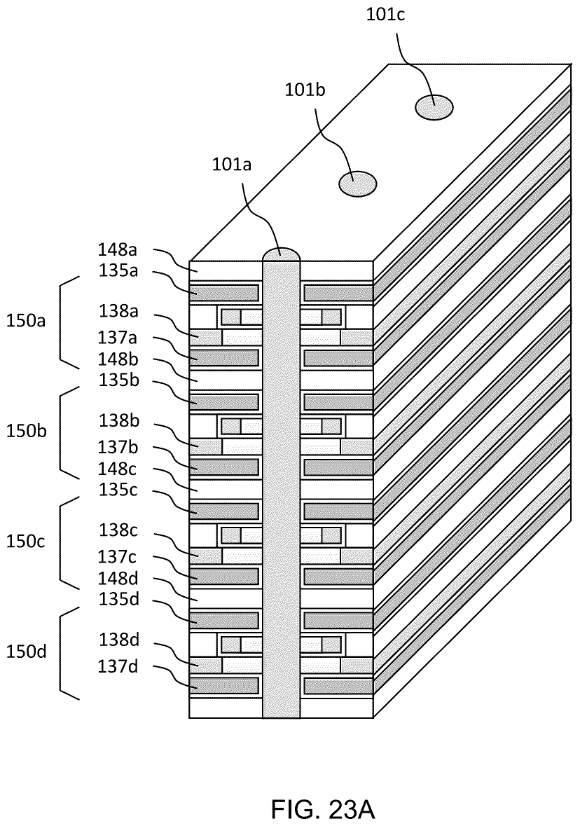

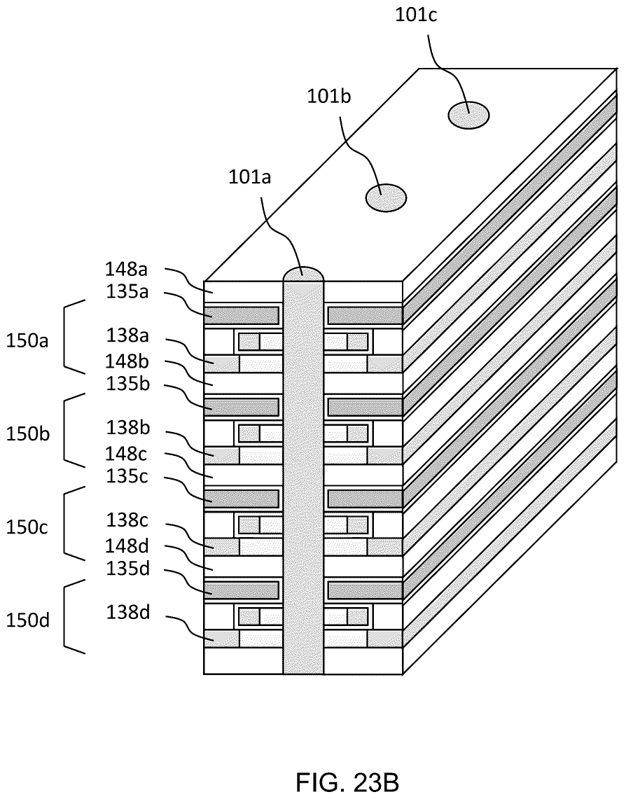

FIG. 23A shows an embodiment of a 3D array structure formed using the cell structure shown in FIG. 13A as an example according to the invention. This 3D array structure can be formed using any of the cell structures shown in FIGS. 13A-21B. The 3D array structure comprises multiple vertical bit lines such as bit lines 101a to 101c. Each bit line is connected to multiple cells such as cells 150a to 150d. The array structure also includes write word lines 135a to 135d, read word lines 137a to 137d, source lines 138a to 138d, and insulating layers 148a to 148d comprising material such as oxide or nitride material between the cells.

FIG. 23B shows an embodiment of 3D array structure formed using the cell structure shown in FIG. 16A as an example according to the invention. This 3D array structure can be formed using any of the cell structures shown in FIGS. 13A-21B. This embodiment is similar to the embodiment shown in FIG. 23A except that the read word lines 137a to 137d are eliminated.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A memory cell structure, comprising:
a vertical bit line;
a first semiconductor layer surrounding a first portion of the vertical bit line;
a first gate surrounding the first semiconductor layer;
a second semiconductor layer surrounding a second portion of the vertical bit line;
a gate dielectric layer surrounding a third portion of the vertical bit line, wherein the gate dielectric layer separates the first semiconductor layer and the first gate from the second semiconductor layer.

2. The memory cell structure of claim 1, wherein the first gate is coupled to the second semiconductor layer to form a first channel region.

3. The memory cell structure of claim 1, further comprising a second gate coupled to the first semiconductor layer to form a second channel region.

4. The memory cell structure of claim 1, further comprising a third gate coupled to the second semiconductor layer to form a third channel region.

5. The memory cell structure of claim 1, further comprising a conductor surrounding the second semiconductor layer.

6. The memory cell structure, comprising:
a vertical bit line;
a first semiconductor layer surrounding a first portion of the vertical bit line;
a first gate surrounding the first semiconductor layer;
a gate dielectric layer surrounding the first semiconductor layer and the first gate; and
a second semiconductor layer surrounding a second portion of the vertical bit line and located below the bottom portion of the gate dielectric layer.

7. The memory cell structure of claim 5, wherein the first gate is coupled to the second semiconductor layer to form a first channel region.

8. The memory cell structure of claim 5, further comprising a second gate coupled to the first semiconductor layer to form a second channel region.

9. The memory cell structure of claim 5, further comprising a conductor surrounding the second semiconductor layer.
